(19) United States
(12) Patent Application Publication
(10) Pub. No.: US 2013/0042903 A1
(43) Pub. Date: Feb. 21, 2013

(54) SOLAR ENERGY GENERATOR

(71) Applicant: Shun Wu Henry Ng, Xiamen City (CN)

(72) Inventor: Shun Wu Henry Ng, Xiamen City (CN)

(21) Appl. No.: 13/695,016

(22) PCT Filed: Dec. 1, 2010
(86) PCT No.: PCT/CN2010/001938

§ 371 Date: Oct. 26, 2012

(30) Foreign Application Priority Data
Apr. 30, 2010 (CN) 201010161170.X

(51) Int. Cl. H01L 31/058; F24J 2/38; F24J 2/04; H01L 31/052

(52) U.S. Cl. 136/248; 136/246; 126/600; 126/634; 126/640

(57) ABSTRACT

An auto-tracking sun solar energy power generator. The power generator includes an eight-diagram-shaped photovoltaic power generator of 8.8 multiples, an eight-diagram-shaped thermal energy generator of 30-50 multiples, a Striling external-combustion photothermal power generator of an eight-diagram-shaped thermal energy generator and a wind-light mutual complementing power generator with the power more than 20 kW. The first three devices are eight-diagram-shaped and of multiple sun structure. The fourth device is a wind-light mutual complementing planar silicon batteries power generator. The first three devices comprise a named multiple suns machine and a named tracking sun machine. The multiple suns machine comprises a metal bracket and planar glass. The tracking sun machine comprises a mechanical drive assembly for tracking sun and a counter-weight.

### FIELD OF THE INVENTION

The present invention relates to an eight-diagram-shaped photovoltaic power generator of 8.8 multiples, an eight-diagram-shaped thermal energy generator of 30-50 multiples, a Striling external-combustion photothermal power generator of an eight-diagram-shaped thermal energy generator, and an imperial wind-light mutual complementing power generator.

### DESCRIPTION OF THE RELATED ART

The conventional photovoltaic power generator has shortcomings that the costs of the silicon battery are so high, and the automatic sun tracking devices are unsustainable and unreliable, especially to the photovoltaic power generator with kW.

The solar energy hot water machines are usually served for providing home water. When the hot water is generated by an eight-diagram-shaped solar hot water machine, the hot water generated accordingly is precious. Wherein, such solar hot water machine is directed to a high-efficient heating system that provides hot water for industry or large buildings. A Striling external-combustion photothermal power generator of an eight-diagram-shaped thermal energy generator is a hopeful and independent power generator.

We expect to properly collect, store, and apply the light and heat from the sun. The present invention promotes the heat-storing efficiency to help human keep warming. When the solar energy generator like the multiple power generator, the thermal energy generator, the photothermal power generator, or the wind-light mutual complementing power generator adopts principles in the ancient Chinese Book of I Ching and the eight diagrams, the solar heat can be properly stored underground. Thus, afore solar energy generator preferably expands the application of solar energy.

### SUMMARY OF THE INVENTION

The solar energy generator of the present invention provides four machines that are designed according to the Chinese ancient book of I Ching and the eight diagrams. The point of the present invention is to design frames of a multiple sun machine, a tracking sun machine, a tracking sun machine with a gear having no teeth, a curve triple counterweight, and an independent device properly. When afore four machines incorporate with techniques in the Striling external-combustion photothermal power generator of an eight-diagram-shaped thermal energy generator, the multiple sun machine, and the tracking sun machine, it is significant for the present invention to develop.

There is an old saying in the Book of I Ching about the eight diagrams, “The none generates the supreme, and the supreme generates the universe.” The eight diagrams imply the farthest points of the universe, and this principle is applied in the present invention.

The present invention is achieved as follows:

1. The gear box of the tracking sun machine is easily broken. The large photovoltaic power generator needs to face up to the sunlight so as to trace the sun track. Herein, in time of starting and stopping the tracing process, the drive force of the gear box is 100 times large to the drive force in time of the regular rotation. Therefore, the gear box easily gets broken. Also, in view of the uncertain weather changes such as the gusty or strong wind, it is difficult to ensure the durability of the gear box. The present invention thence utilizes the tracking sun machine with the gear having no teeth to solve afore problems. Namely, the independent machine of the power generator with the power more than 20 kW provides a reliable condition of the charging of the electronic autos in the future.

2. The eight-diagram-shaped bracket of the tracking sun machine is not just a simple annular structure. Only when the sunlight is efficiently collected during the sunrise and the sunset, the solar energy can be properly controlled and utilized. The symbols of the heaven, swamp, fire, thunder, wind, water, mountain, and earth in the Book of I Ching are arranged on an eight-diagram-shaped planar glass set. Namely, the collected sunlight will be calculated and controlled. The design of the present invention needs no particular optical glass, and the bracket is directed to the common tripod. Therefore, it is evident that the costs of the present invention are not high.

3. This eight-diagram-shaped machine is not a round shape. Namely, the machine itself points the east, west, south, and north, respectively. Interstices among the machine help wind go through, the bracket thereof lessens the weight of the machine, and the planar glass set can be covered properly. While the illuminances of the sunlight are different due to that different locations have various latitudes, the glass set can be covered for controlling. Moreover, the independent photothermal power generator is able to generate different watts, so that this type of machine is especially suited to large buildings or villas.

4. The curve triple counterweight of the present invention is different from the common counterweight. Namely, the setting position and angle of the triple counterweight are correlated to the tracking technique.

5. The multiple sun machine is a machine that provides several suns. Namely, this structure allows the sun to be reflected to the reversely suspended silicon sun battery. Thus, the silicon battery is turned from “yang” (the bright side) to “yin” (the dark side), and the planar glasses are able to reflect the sunlight, so that multiple beams of sunlight are overlapped on the battery board. Accordingly, the solar energy is enhanced since the amount of sun is increased. Namely, the multiple sun machine assumes that there are nine suns in the sky.

The photovoltaic power generator of the silicone battery needs to be kept under 60 Celsius degrees. The heating temperature caused during the silicon battery generating multiple power is cooled by water. The water for cooling can be also served as home water.

6. The multiple sun machine generates power efficiently. When the battery progressively adopts superior materials, and when the machine generates power more efficiently, the present invention offers more economic value. Favorably, the multiple sun machine performs well in generating and storing heat.

7. The planar glasses arranged with the eight-diagram-shaped bracket allow the positioning angle of the bracket that collects the solar energy to be countable and controllable, including the loss of the sunlight cosine. It is important to realize the related data for manufacturing the photovoltaic power generator. When the photovoltaic power generator is used either in the equator or in the Southern/Northern Hemisphere, the glasses have to be properly covered for controlling the energy.

8. The Striling external-combustion photothermal power generator of an eight-diagram-shaped thermal energy generator has advantages in that different specifications of the independent-typed photothermal power generators can be efficiently manufactured. The sunlight is stored under the thermal energy generator or underground. The correlated heat storing technique is efficient but simple, and the costs thereof are also not high. Especially, it is easy to transmit the temperature about 300 Celsius degrees to the water pipes. Therefore, hot water for living or keeping warming can be provided to the large buildings. Accordingly, it is significant when the hot oil is directly or indirectly provided to the Striling power generator for generating power externally. Preferably, the process of power generation can be conducted on the ground.

9. Afore machines focus on the mechanical structures; other electronic elements applied in the automatic machines are not to be discussed.

### ADVANTAGES OF THE PRESENT INVENTION ARE AS FOLLOWS

1. The wind-light mutual complementing power generator of the solar-energy-typed photovoltaic power generator of the present invention utilizes a clamping transmission that presses and rotates via pressing wheels provided with heavy springs being motivated on an annular slideway. Such structure is suited to the large wind power generator or the wind-light mutual complementing power generator of the solar-energy-typed photovoltaic power generator. The bracket of the wind-light mutual complementing power generator is situated on a same cement base. Namely, a frame of the wind power generator is situated on the center, and frames of the silicon sun battery are situated on the edge. These two machines have no relationship so as to achieve the purpose of a separate wind-light mutual complementing power generating. A latitude rotation is achieved via the clamping transmission, and a longitude rotation is achieved via the motivation of a worm reducer. Accordingly, the object of the large wind-light mutual complementing power generation is attained.

2. A heat collector suspended on a center of the eight-diagram-shaped planar glass set allows the liquid in a circular metal conduit to conduct heat exchange with the liquid in another circular metal conduit in a heat storeroom outside. The temperature of a case of the heat storeroom is kept via a thermal insulation material. There is the circular metal conduit in the heat storeroom, and the water or chemical liquid in the conduit utilized during the heat exchange can be further applied in the industry or in the home. The heat collecting effect is at least fifteen times more than that of the conventional structure. There are a metal reflector and a thermal insulation material suspended on the circular metal conduit. An upper layer of the thermal insulation material accommodates a silicon sun battery plate for providing a loop pump, a water pump and a lighting apparatus of the heat storeroom with electricity.

The following embodiments are depicted along with the figures below.

### BRIEF DESCRIPTION OF THE DRAWINGS

FIG. 1 is a schematic view showing three layers of twenty-four planar glasses providing electricity of 8.8 multiples;

FIG. 2 is a schematic view showing five layers of sixty-four planar glasses collecting heat of 15 to 30 times;

FIG. 3 is a perspective view showing a photovoltaic power generator of 8.8 multiples (cooling water);

FIG. 4 is a perspective view showing a thermal energy generator of 30 multiples;

FIG. 5 is a perspective view showing a wind-light mutual complementing power generator of the kW type;

FIG. 6 is a schematic view showing three clamping wheels;

FIG. 7 is a schematic view showing a conventional tracking sun machine; and

FIG. 8 is an machine oil heat storing machine of 30 multiples providing 300 Celsius degrees.

### DETAILED DESCRIPTION OF THE PREFERRED EMBODIMENTS

### First Preferred Embodiment

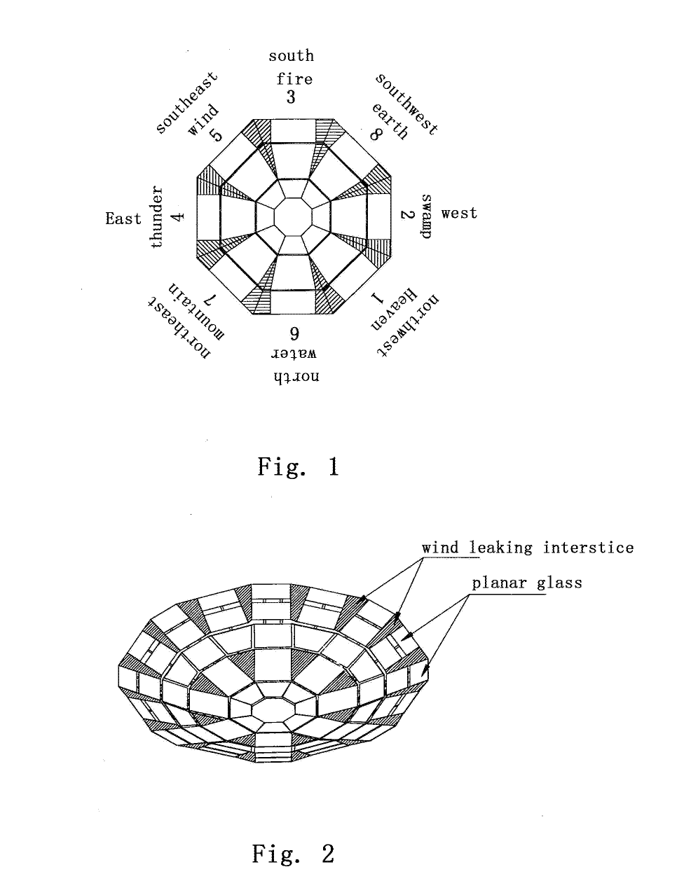

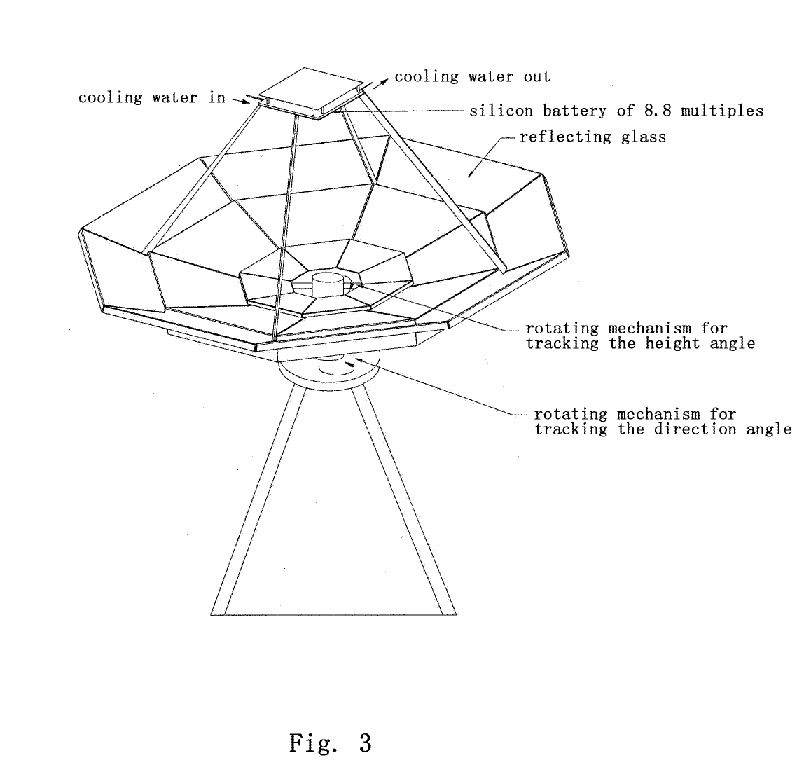

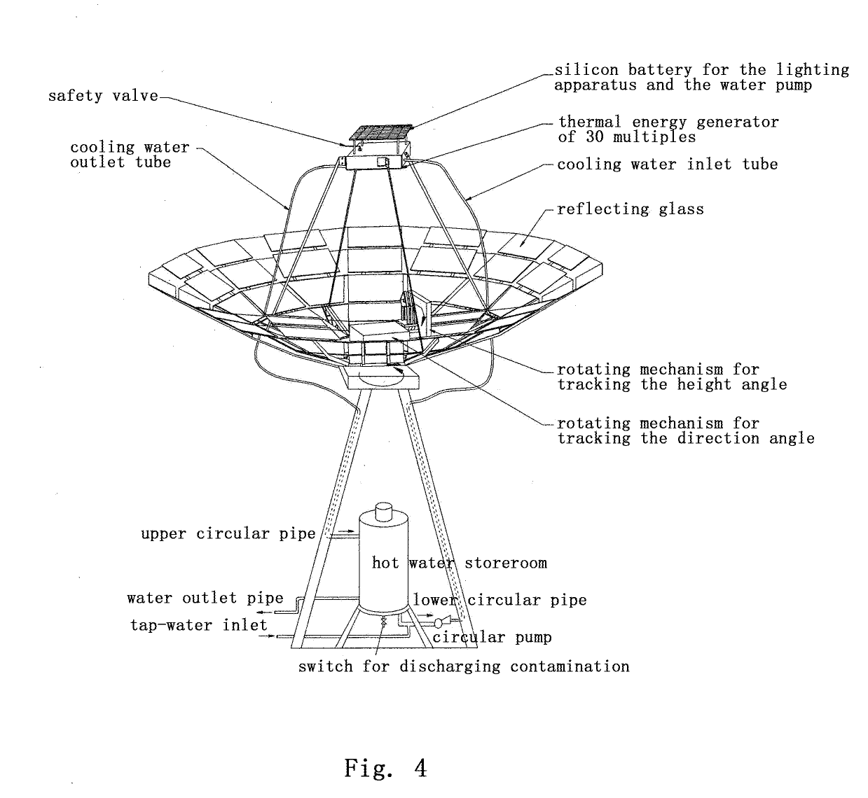

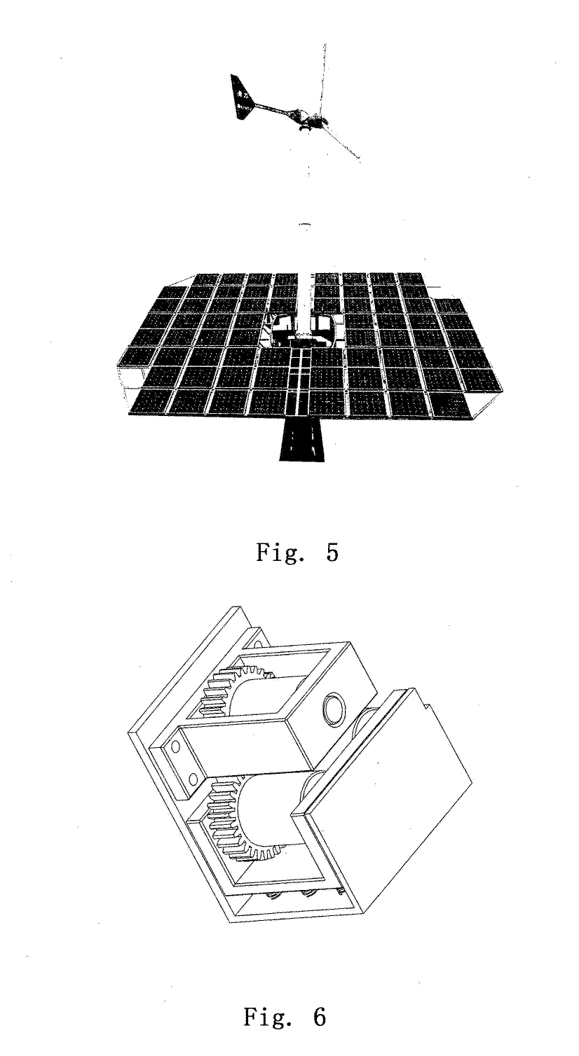

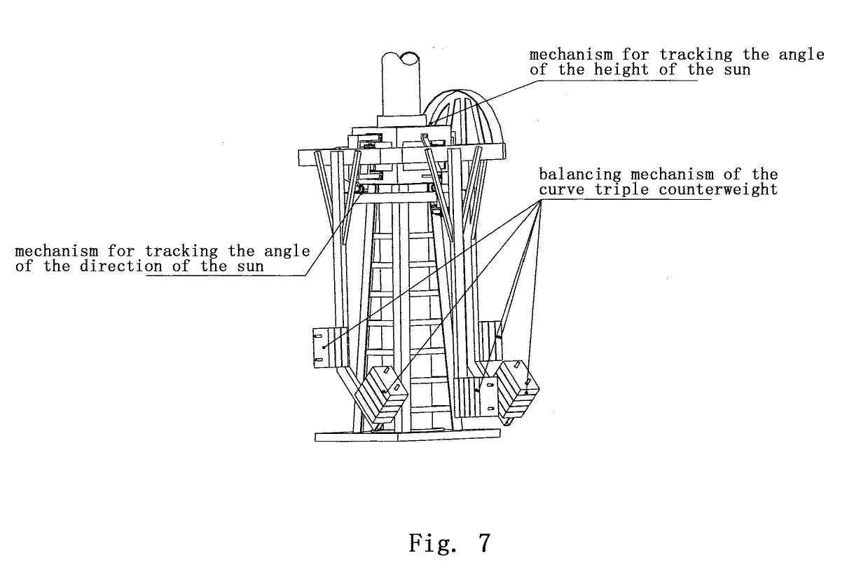

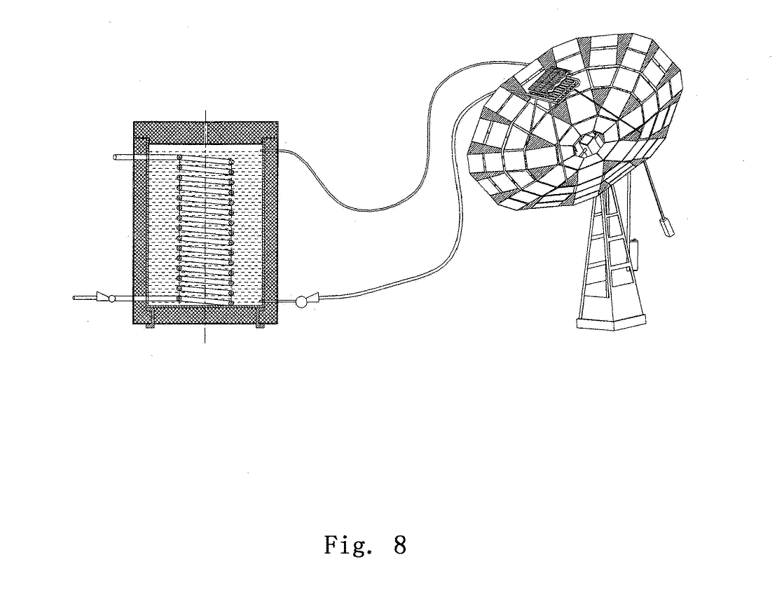

FIGS. 1 to 3 show a wind-light mutual complementing power generator of the solar energy utilizes a clamping transmission via separating the wind and the light. The power generator comprises a wind-power generator frame 1 fixed to a cement base 5, and a silicon sun battery frame disposed outside the wind-power generator frame 1. The silicon sun battery frame includes a longitude spindle rotating around the wind-power generator frame 1. Referring to FIGS. 4 and 5, the longitude spindle has an annular slideway 32 that allows two engaging wheels 31 of heavy springs 33 to slide thereon, which provides a clamping transmission via pressing and rotating. The annular slideway 32 is fixed around the wind-power generator frame 1. The silicon sun battery frame further includes a latitude spindle 21 parallel to a vertical surface of the wind-power generator frame 1 for moving. Two sides of the latitude spindle 21 are fixed and connected to two counterweights 41. Wherein, the wind-power generator frame 1 has a rotation sleeve 22 that provides a rotation frame 23 outward extended therefrom. The latitude spindle 21 is rotatively pivoted to the rotation frame 23. A rotating part is rotatively connected to the longitude spindle. The engaging wheel 31 is fixed and connected to the rotation frame 23. The counterweight 41 is disposed to a frame 42 pivoted to the rotation frame 23.

### Second Preferred Embodiment

The present invention is designed according to the ancient eight-diagram principles and in accordance with the natural and regular pattern of the sunrise and the sunset. Referring to FIG. 1, a large eight-diagram-shaped hot oil/water machine for industry comprises an eight-diagram-shaped planar glass set 1 arranged in accordance with the symbols in the eight diagrams, namely, heaven, swamp, fire, thunder, wind, water, mountain, and earth. Each glass set includes at least one inclined planar glass unit arranged in sequence. Every planar glass unit reflects the sunlight on a light receiving surface of a suspended and reversed circular metal conduit 2. Several eight-diagram-shaped planar glass sets 1 are respectively arranged on eight extended supporting frames correspondingly so as to form the eight diagrams. The eight-diagram-shaped planar glass set includes at least sixteen or twenty-four glasses for conducting the thermal energy generation. A heat collector suspended on a center of the eight-diagram-shaped planar glass set 1 is formed by a circular metal conduit 2 that includes a metal reflector 6 disposed thereon, a heat insulating layer 10, and a silicon sun battery 7. When a heat storeroom 3 is further provided, the liquid in the circular metal conduit 2 is utilized to conduct heat exchange with the liquid in the heat storeroom through a loop conduit 4. The heat storeroom 3 is wrapped in a thermal insulation material 8. In the storeroom, there is a circular metal conduit 9, and a loop pump 5 is further connected between the heat storeroom 3 and the circular metal conduit 2 of the heat collector. The silicon sun battery 7 is connected to the loop pump 5. The silicon sun battery 7 provides the loop pump 5 with electricity and offers electricity to a water pump 11 and a lighting apparatus connected to the heat storeroom 3.

The liquid in the circular metal conduit 2 of the heat collector is conducted by the heat exchange with the liquid in the circular metal conduit 9 of the heat storeroom 3 disposed outside. The heat storeroom 3 stores heat about 300 degrees, and the heat energy can be utilized in the large industrial hot water machine and the hot oil machine.

I claim:

1. An auto-tracking sun solar energy power generator comprising four independent devices that generate electricity and heat through solar energy: the first device being an eight-diagram-shaped photovoltaic power generator of 8.8 multiples; the second device being an eight-diagram-shaped thermal energy generator of 30-50 multiples; the third device being a Striling external-combustion photothermal power generator of an eight-diagram-shaped thermal energy generator; and the fourth device being a wind-light mutual complementing power generator with the power more than 20 kW; the first three devices being eight-diagram-shaped and of multiple sun structure; the fourth device being a wind-light mutual complementing planar silicon batteries power generator (with an eight-diagram-shaped bracket);
the first three devices comprising a named multiple suns machine and a named tracking sun machine (for tracking sun); said multiple suns machine comprising a metal bracket and planar glass; said tracking sun machine comprising a mechanical drive assembly for tracking sun and a counter-weight; said first three devices having the same structure, they providing the same drive assembly for tracking sun, and they offering the same metal bracket, so they are named tracking sun machine;
said tracking sun machine and said multiple sun machine being also called as said eight-diagram-shaped photovoltaic power generator, said eight-diagram-shaped thermal energy generator, or a Striling external-combustion photothermal power generator of an eight-diagram-shaped thermal energy generator; said fourth device being said wind-light mutual complementing power generator with the power more than 20 kW of a large plane (including said eight-diagram-shaped bracket); said mechanical drive assembly for tracking sun of said fourth device also having the same structure as that of afore three devices; differently, said eight-diagram-shaped metal bracket being served as a base frame of a planar type since there is no planar glass on said bracket; thus no piled structure being included.

2. The solar energy generator as claimed in claim 1, wherein, said multiple sun machine arranges eight parts in accordance with eight diagrams on said metal bracket for installing eight planar glasses; said planar glasses are arranged on multiple layers of said metal bracket outward and upward; so that the sun is reflected and overlapped on a suspended and reversed silicon sun battery for generating power through photovoltaic; eight glasses can be installed on one layer of said eight parts, sixteen glasses can be installed on two layers of said eight parts, twenty-four glasses can be installed on three layers of said eight parts, and so on; according to the Book of Changes (I Ching), said eight parts on said metal brackets are directed to heaven, swamp, fire, thunder, wind, water, mountain, and earth; said thunder, fire, swamp, and water are pointed to east, south, west, and north, respectively; said planar glasses correlated to afore four directions are arranged as a square shape; said wind, earth, mountain, and heaven are pointed to southeast, southwest, northeast, and northwest, respectively; said planar glasses correlated to afore four directions are arranged as a rhombus.

3. The solar energy generator as claimed in claim 1, wherein, said multiple sun machine arranges an aluminum plate that is tightly pressed and connected on a suspended and reversed silicon sun battery; a circular cooling sink in said plate circularly cools a silicon battery plate via a water pump, so that an operating temperature of said silicon battery plate can be controlled under 65 Celsius degrees; water for cooling can be served as home water.

4. The solar energy generator as claimed in claim 1, wherein, said multiple sun machine suspends a metal can for being loaded with water or machine oil; said eight-diagram-shaped bracket includes five or six layers; sixty-four glasses are arranged within the five layers; there are twenty planar glasses and twenty auxiliary reflecting glasses installed on a main reflecting glass; the other twenty-four planar glasses are installed in leaking interstices between any two brackets; thus there are sixty-four planar glasses; said planar glasses of each layer are placed in a certain angle for sun light to evenly distribute over a shone surface of said metal can; this machine is so-called eight-diagram-shaped thermal energy generator.

5. The solar energy generator as claimed in claim 4, wherein, said eight-diagram-shaped thermal energy generator allows more planar glasses or more layers than the sixty-four planar glasses to face a suspended heat collector that is loaded with machine oil or other like substances; herein, said substances acquire thermal energy of 30 to 50 multiples, and said thermal energy can be circularly stored in a heat storeroom;
characterized in that,
(1) said heat storeroom of a circular type is set under a frame of said independent thermal energy generator or under ground; heating machine oil about 300 Celsius degrees in said heat storeroom allows a circular metal conduit to be installed for heating circulating water, so that said water can be served as industry water or for indoor warming;
(2) said heat storeroom of circular type is set under said frame of said independent thermal energy generator or underground; said heating machine oil or other substance in said heat storeroom is served as an external heating source for said Striling power generator to conduct photothermal power generation.

6. The solar energy generator as claimed in claim 1, wherein, said tracking sun machine includes said photovoltaic power generator, said thermal energy generator, said photothermal power generator, and said wind-light mutual complementing power generator with the power more than 20 kW of a large planar type; an automatic tracking sun drive reducer is directed to a slidable structure of a gear having no teeth; namely, said slidable drive reducer is a tracking sun sliding structure that ensures its safety while multiple force is caused by acceleration in time of starting and launching.

7. The solar energy generator as claimed in claim 1, wherein, said tracking sun machine adopts a vertically curve slideway; a gear having no teeth is served for tracking and adjusting according to an angle of the height of the sun; a horizontally curve slideway is also adopted; another gear having no teeth is served for tracking an angle of the direction of the sun; said curve slideways eliminate uncertainty caused by acceleration in view of multiple force or gusty wind occurred in time of starting and launching; namely, if overloaded, the sliding protects a gear box, and said vertically curve slideway as well as said horizontally curve slideway plus an electronic control cooperatively achieves a simple but precise and reliable sun tracking process.

8. The solar energy generator as claimed in claim 1, wherein, a curve triple counterweight is adopted by automatic tracking solar energy brackets of said solar photovoltaic power generator, said thermal energy generator, said Striling external-combustion photothermal power generator of an eight-diagram-shaped thermal energy generator, and said wind-light mutual complementing power generator with the power more than 20 kW of a large planar type; thus said triple counterweight ensures a complicated program for tracking sun to be completed but reduces energy consumption of said tracking sun structure; said counterweight includes a single middle straight counterweight and two east-west curve counterweights; a frame of said single straight counterweight suspends a cement counterweight, and a frontward-protruded frame of said two east-west curve counterweights is bended about 130 degrees for suspending said cement counterweight.

9. The solar energy generator as claimed in claim 1, wherein, said wind-light mutual complementing power generator arranges a wind power generator frame to be disposed on a center of said power generator; a silicon sun battery frame is arranged around said wind power generator frame for being situated on a same base but having no relationship; said wind power generator and said silicon sun battery share an electronic control; a planar silicon sun battery is situated on said eight-diagram-shaped bracket; a tracking sun structure of said planar silicon sun battery is same as that of afore tracking sun machine.
